(19) United States
(12) Patent Application Publication
(10) Pub. No.: US 2011/0203644 A1
(43) Pub. Date: Aug. 25, 2011

(54) QUASI-SOLID-STATE PHOTOELECTROCHEMICAL SOLAR CELL FORMED USING INKJET PRINTING AND NANOCOMPOSITE ORGANIC-INORGANIC MATERIAL

(75) Inventors: Panagiotis Lianos, Aghios Vassilios Rion (GR); Elias Stathatos, Patras-Greece (GR)

(73) Assignee: BRITE HELLAS AE, Pylaia-Thessaloniki (GR)

(21) Appl. No.: 12/986,181

(22) Filed: Jan. 7, 2011

Related U.S. Application Data
(60) Provisional application No. 61/306,546, filed on Feb. 22, 2010.

(51) Int. Cl. H01L 31/0264; H01L 31/18

(52) U.S. Cl. 136/252; 438/93; 257/E31.003

(57) ABSTRACT

Methods and apparatus are disclosed regarding photoelectrochemical solar cells formed using inkjet printing and nanocomposite organic-inorganic materials, such as for converting solar energy into electricity. An exemplary solid photoelectrochemical solar cell formation includes thin layers of nanocomposite organic-inorganic materials. A specific exemplary solid photoelectrochemical solar cell may include: a negative electrode comprising a transparent electroconductive glass plate; a thin transparent film of mesoporous nanocrystalline titanium dioxide of controlled thickness above the negative electrode, formed by dip-coating, spin-coating or inkjet printing, and having a photosensitizer dye comprising a ruthenium organometallic complex, a merocyanine dye, or a hemicyanine dye; a layer of a solid gel electrolyte formed above the titanium dioxide layer and including a nanocomposite organic-inorganic material and a redox couple; and a positive electrode comprising a second electroconductive glass plate having a thin layer of deposited electrocatalyst made of platinum, carbon, or both, in the form of nanostructures, including nanoparticles, nanotubes, conjugated conductive polymers, or their mixtures.

### CROSS REFERENCE TO RELATED APPLICATION

This application is related to and claims the benefit of U.S. Provisional Patent Application Ser. No. 61/306,546 (“the '546 application”), titled “Photoelectrochemical Solar Cell Including Nanocomposite Organic-Inorganic Materials,” and filed Feb. 22, 2010, which is incorporated by reference herein in its entirety for all purposes.

### STATEMENT REGARDING SPONSORSHIP OF DEVELOPMENT

Aspects of the invention described herein are the result of development co-financed by Hellenic Funds and by the European Regional Development Fund (ERDF) under the Hellenic National Strategic Reference Framework (NSRF) 2007-2013, according to contract MICRO2-32 of the project “Development of Semitransparent Solar Panels” within the Program “Hellenic Technology Clusters in Microelectronics-Phase-2 Aid Measure.”

### BACKGROUND OF THE INVENTION

1. Field of the Invention

The invention relates to methods and apparatus of a Photoelectrochemical Solar Cell (“PECSC”). Proposed uses include photovoltaic (“PV”) applications, such as for converting solar energy into electrical energy (“PV conversion”) and, generally, for the conversion of light signals into electrical signals, inasmuch as a PV device is an optoelectronic sensor of light.

2. Description of Related Art

The related art includes, for instance, versions of a PECSC described in international journal publications: O'Reagan, B.; Graetzel, M. Nature, 1991, 353, 737; and Nazeeruddin, M. K.; Kay, A.; Rodicio, I.; Humphry-Baker, R.; Mueller, E.; Liska, P.; Vlachopoulos, N.; Graetzel, M.; J. Am. Chem. Soc. 1993, 115, 6382 and in U.S. Pat. No. 5,350,644 to Graetzel et al. Other prior art cells include those described in the international journal publication: E. Stathatos, P. Lianos, U. Lavrencic-Stangar, B. Orel, Adv. Mater., 2002, 14, No. 5, 354 and protected by Greek Patent OBI, No. 1003816. The prior art cells, however, are formed using methods and materials different from those of the invention.

### BRIEF SUMMARY OF THE INVENTION

The invention is directed to methods and apparatus involving a quasi-solid-state cell comprising a multilayer film, based on nanocomposite organic-inorganic materials. The nanocomposite organic-inorganic materials may be synthesized, for instance, by purely chemical processes and deposited by various techniques including inkjet-printing under ambient conditions. In particular, the invention involves formation of a cell using novel processes for the synthesis and deposition of titanium dioxide (“TiO₂” or “titania”). In accordance with aspects of the invention, an active surface area of a TiO₂ film is increased, which accordingly increases the quantity of adsorbed organic photosensitizer and increases overall efficiency of the cell.

An increase in efficiency also may be achieved by using a solid gel electrolyte having electric conductivity-enhancing components incorporated in the electrolyte. The solid gel electrolyte may provide several advantages, including that it may obviate the need to separately seal the cell because it is self-sealing, which greatly decreases cell assembly cost. Separate sealing materials not only add to materials and assembly costs, but they waste an important part of the surface of the cell, thus decreasing cell active surface. The embodiments of invention may make optimal use of cell surface since no parts are covered by sealing materials.

Finally, an exemplary gel electrolyte may be very thin, much thinner than electrolyte layers in previous art cells. The thickness of the gel electrolyte, according to cross-sectional images, varies from about 50 to about 80 micrometers, depending to its contents. Therefore, ohmic losses are lower in cells formed in accordance with embodiments of the invention.

In accordance with a first aspect of the invention, a method of forming a photoelectrochemical solar cell is disclosed, wherein the method comprises: forming a titanium dioxide layer by inkjet printing on a first electrode; adding a dye to the titanium dioxide layer; forming an electrolyte solid gel above the titanium dioxide layer; and disposing a second electrode above the solid gel. The method may further comprise forming an electrocatalyst layer on the second electrode.

In accordance with a second aspect of the invention, a solar cell is disclosed, wherein the solar cell comprises: a first electrode; a titanium dioxide layer formed by inkjet printing on the first electrode and comprising a dye; a solid gel electrolyte disposed above the titanium dioxide layer; and a second electrode disposed above the solid gel.

In accordance with a third aspect of the invention, a photovoltaic window is disclosed, wherein a transparent window comprises a transparent solar cell, and wherein the transparent solar cell comprises: a first electrode comprising a first transparent conductive glass plate; a transparent titanium dioxide layer formed by inkjet printing on the first electrode and comprising a dye; a transparent solid gel electrolyte disposed above the transparent titanium dioxide layer; and a second electrode disposed above the solid gel.

In accordance with a fourth aspect of the invention, a solar cell is disclosed, wherein the solar cell comprises: a first electrode; a titanium dioxide layer formed on the first electrode and comprising a dye; a solid gel electrolyte disposed above the titanium dioxide layer; and a second electrode disposed above the solid gel, wherein the second electrode comprises a second transparent conductive glass plate and an electrocatalyst, wherein the electrocatalyst comprises platinum, carbon, or both, comprising nanoparticles, nanotubes, conjugated conductive polymers, or a mixture thereof.

In accordance with a fifth aspect of the invention, a solar cell is disclosed, wherein the solar cell comprises: a first electrode; a titanium dioxide layer formed on the first electrode and comprising a dye; a solid gel electrolyte disposed above the titanium dioxide layer; and a second electrode disposed above the solid gel, wherein the solid gel comprises a redox couple comprising iodine (I₂), potassium iodide (KI), and 1-methyl-3-propylimidazole iodide.

In accordance with a sixth aspect of the invention, a solar cell is disclosed, wherein the solar cell comprises: a first electrode; a titanium dioxide layer formed on the first electrode and comprising a dye; a solid gel electrolyte disposed above the titanium dioxide layer; and a second electrode disposed above the solid gel, wherein the solid gel comprises 1-methylbenzimidazole, 2-amino-1-methylbenzimidazole, guanidine thiocyanate, or 4-tertiary butyl pyridine.

In accordance with a seventh aspect of the invention, a solar cell is disclosed, wherein the solar cell comprises: a first electrode; a titanium dioxide layer formed on the first electrode and comprising a dye; a solid gel electrolyte disposed above the titanium dioxide layer; and a second electrode disposed above the solid gel, wherein the dye comprises a photosensitizer, and wherein the photosensitizer comprises a ruthenium organometallic complex dye, a merocyanine dye, or a hemicyanine dye.

In accordance with an eighth aspect of the invention, a solar cell is disclosed, wherein the solar cell comprises: a first electrode; a titanium dioxide layer formed on the first electrode and comprising a dye; a solid gel disposed above the titanium dioxide layer; and a second electrode disposed above the solid gel, wherein the solid gel comprises an electrolyte layer having a thickness of between about 50 and about 80 micrometers.

In accordance with a ninth aspect of the invention, a solar cell is disclosed, wherein the solar cell comprises a self-sealing layer stack comprising: a first electrode; a titanium dioxide layer formed on the first electrode and comprising a dye; a solid gel disposed above the titanium dioxide layer; and a second electrode disposed above the solid gel, wherein the solid gel comprises a very thin electrolyte layer comprising a stable adhesion layer between the first electrode and the second electrode. The stable adhesion layer durably adheres the first electrode and the second electrode, and self-seals the layer stack, by gelatinization of the solid gel after the very thin electrolyte layer is compressed between the first electrode and the second electrode.

In accordance with a tenth aspect of the invention, a method of forming a solar cell is disclosed, wherein the solar cell comprises a self-sealing layer stack, and wherein the method comprises: forming a titanium dioxide layer on a first electrode; adding a dye to the titanium dioxide layer; forming a solid gel above the titanium dioxide layer; and disposing a second electrode above the solid gel; wherein the solid gel comprises a very thin electrolyte layer comprising a stable adhesion layer between, and durably adhering, the first electrode and the second electrode; wherein forming the solid gel comprises self-sealing the layer stack; wherein self-sealing the layer stack comprises forming the stable adhesion layer; wherein forming the stable adhesion layer comprises compressing the very thin electrolyte layer between the first electrode and the second electrode, and then gelatinizing the very thin electrolyte layer. Forming the stable adhesion layer may further comprise partially gelatinizing the very thin electrolyte layer before compressing the very thin electrolyte layer between the first electrode and the second electrode.

In accordance with an eleventh aspect of the invention, a solar cell is disclosed, wherein the solar cell comprises: a first electrode; a titanium dioxide layer formed on the first electrode and comprising a dye; a solid gel electrolyte disposed above the titanium dioxide layer; and a second electrode disposed above the solid gel, wherein the second electrode comprises a second transparent conductive glass plate and an electrocatalyst deposited on the glass plate, wherein the electrocatalyst is deposited by inkjet printing.

The details of exemplary embodiment of the invention are set forth in the accompanying drawings and the description below. Other features, objects, and advantages of the invention will be apparent from the description and drawings, and from the claims.

### BRIEF DESCRIPTION OF THE DRAWINGS

By reference to the appended drawings, which illustrate an exemplary embodiment of this invention, the detailed description provided below explains in detail various features, advantages and aspects of this invention. As such, features of this invention can be more clearly understood from the following detailed description considered in conjunction with the following drawings, in which the same reference numerals denote the same elements throughout. The exemplary embodiment illustrated in the drawings is not intended to be to scale and is not to be considered limiting of its scope, for the invention may admit to other equally effective embodiments.

FIG. 1 shows a cross-sectional elevation view of an exemplary embodiment of the invention.

FIG. 2 shows a plan-view atomic force microscope (“AFM”) image of an exemplary titania film.

FIG. 3 shows a perspective-view AFM image of the exemplary titania film.

FIGS. 4A and 4B show plan-view field emission scanning electron microscope (“FE-SEM”) images of an exemplary titania film, in lower magnification (FIG. 4A) and higher magnification (FIG. 4B).

FIG. 5 shows exemplary adsorption spectra of a titania film without an adsorbed dye (curve 1) and with an adsorbed dye (curve 2). FIG. 6 depicts an exemplary chemical structure of the adsorbed dye of FIG. 5.

FIG. 7 shows an exemplary J-V characteristic curve of an exemplary embodiment of the invention.

### DETAILED DESCRIPTION

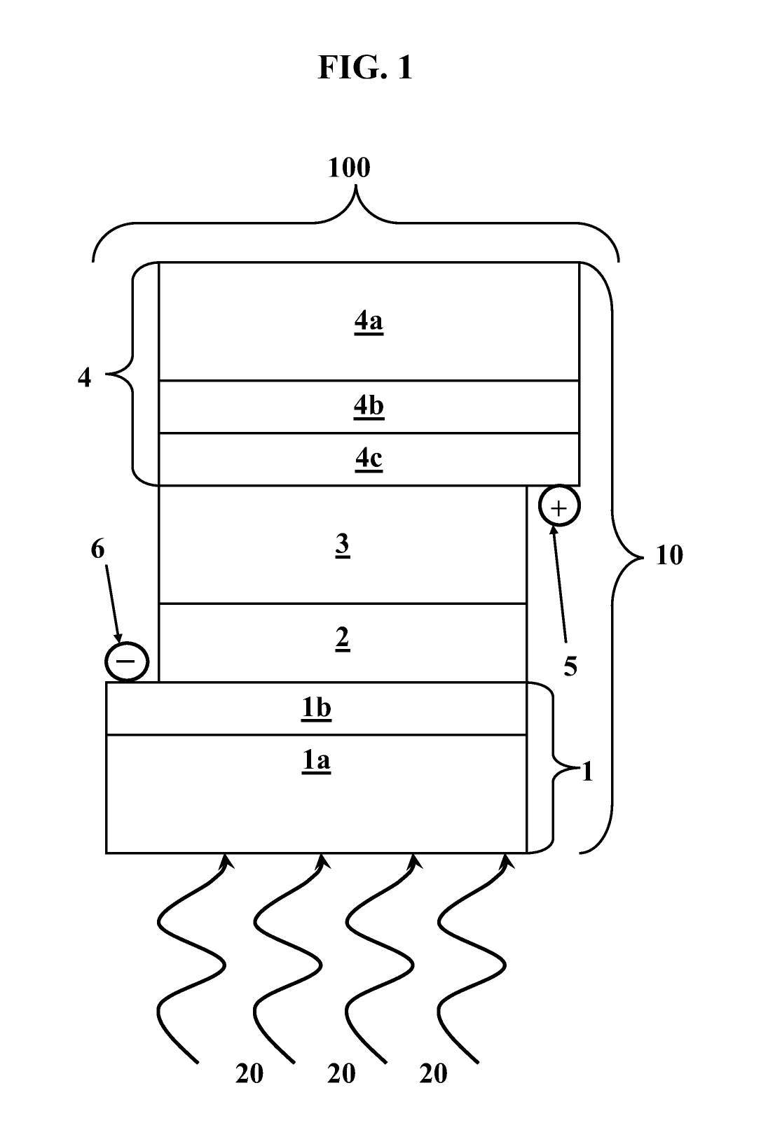

As shown in FIG. 1, an exemplary PECSC 100 according to the invention may include, for example, a layer stack 10 having layers that include a negative electrode 1; a film 2 with a dye; an electrolyte solid gel 3 containing a reduction/oxidation (“redox”) couple; and a positive electrode 4. Positive electrode 4 may be coupled to ohmic contact 5, whereas negative electrode 1 may be coupled to ohmic contact 6. PECSC 100 may convert waves of incident light 20 into electricity through photoelectrochemical activity occurring across layers 1, 2, 3 and/or 4.

In some embodiments of a PECSC 100 according to the invention, other layers may be present to meet design or production functions. In exemplary embodiments of the invention that are intended to be transparent, any layer added to layer stack 10 preferably would be transparent.

Negative electrode 1 may include a first electroconductive glass plate 1, for instance. First electroconductive glass plate 1 may be translucent in some embodiments, and in the exemplary embodiment of FIG. 1, first electroconductive glass plate 1 is transparent. In some embodiments, first electroconductive glass plate 1 may include a possibly non-conductive glass plate 1a having a thin deposited transparent film 1b of tin dioxide doped with fluorine (“SnO₂:F”) that gives electroconductive properties to a deposition surface of glass plate 1a. A suitable composition of SnO₂:F is believed to be commercially available. In further embodiments, glass plate 1a may have a thin deposited transparent film 1b of indium oxide doped with tin (“ITO”), which also is believed to be commercially available. More broadly, negative electrode 1 may include any type of transparent electroconductive plate that provides electric conductivity with a sheet resistance of less than or equal to about 20 Ohm/sq., and preferably less than or equal to about 10 Ohm/sq.

Film 2 may include, for example, a layer of titanium dioxide having a mesoporous structure, which may comprise, for instance, nanocrystals of anatase or of a mixture of anatase and rutile. Exemplary embodiments of film 2 comprise a thin transparent film of controlled thickness. Film 2 may be synthesized, for example, by chemical processes, and deposited by various techniques including inkjet printing as described below. Inkjet printing may result in a pattern characteristic of layer application, making an inkjet-applied layer distinguishable from a spin-cast layer, for instance. As indicated in later Examples 22-28, below, inkjet printing of titania yielded a film 2 having better structural properties and results than a film 2 formed by drip stretching. A layer consisting of pure titanium dioxide is inorganic, but some residual organic material from an organic solvent may remain in the titanium dioxide making it an organic-inorganic layer.

Film 2 includes a dye for interaction with incident light 20. In exemplary embodiments, the dye is adsorbed by film 2 (e.g., the dye accumulates at a surface of film 2), whereas in other embodiment, the dye may be absorbed by film 2 (e.g., the dye is present within film 2). The dye of film 2 may include a photosensitizer of titania, for instance, the commercially available organometallic ruthenium complex, cis-bis(isothiocyanato)bis(2,2′-bipyridyl-4,4′-dicarboxylato)-ruthenium(II) (the chemical structure of which is depicted in FIG. 6), that may be loaded, i.e., adsorbed and/or absorbed, for instance, by dipping a substrate having a surface comprising a titania layer into a solution of the ruthenium complex. Also, in some embodiments, the dye of film 2 could comprise one of the following: (#1) cis-disothiocyanato-bis(2,2′-bipyridyl-4,4′-dicarboxylato) ruthenium(II)tetrakis (tetrabutylammonium), (#2) triisothiocyanato-(2,2′:6′,6″-terpyridyl-4,4′,4″-tricarboxylato) ruthenium(II) tris(tetra-butylammonium), (#3) 2-((E)-5-((1,2,3,3a,4,8b-hexahydro-4-(4-(2,2-diphenylvinyl)phenyl)cyclopenta [b]indole-7-yl)methylene)-3-ethyl-5-(3-carboxymethyl-4-oxo-thiazolidin-2-ylidene) rhodamine, and (#4) aminostilbazium dye with carboxylic groups; or any other commercial dye that can act as photosensitizer of TiO₂. Adsorption of an organic dye on TiO₂ results in a composite film 2 that is an organic-inorganic layer.

Solid gel 3 may comprise a layer of solid gel (“sol-gel”) electrolyte. The sol-gel electrolyte may be made by one of the sol-gel methods described in detail below. An exemplary resulting solid gel material may contain SiO₂, which is inorganic, and polypropylene oxide groups, which are organic, so solid gel 3 may be considered to be organic-inorganic material. Solid gel 3 contributes to a quasi-solid-state nature of the layer stack 10. In this context, a “quasi-solid” state refers to a jelly-like state of a gel after gelatinization occurs. Solid gel 3 may comprise a very thin electrolyte layer comprising a stable adhesion layer between first electrode 1 and second electrode 4. The stable adhesion layer may durably adhere first electrode 1 and second electrode 4, and self-seals layer stack 10, by gelatinization of solid gel 3 after the very thin electrolyte layer is compressed between first electrode 1 and second electrode 4.

Positive electrode 4 may comprise, for instance, an electroconductive glass plate. Electroconductive glass plate may resemble negative electrode 1, using, for instance, a glass plate 4a having a conductive layer 4b, such as SnO₂:F or ITO, to complete the cell. In the exemplary embodiment of FIG. 1, positive electrode 4 may include, for example, a transparent electroconductive glass plate 4a, 4b having a thin electrocatalyst layer 4c. Thin electrocatalyst layer 4c may comprise, for example, platinum (“Pt”) or carbon (“C”), in a form of nanoparticles, including nanotubes, or conjugated conductive polymers. The thin layer of Pt may be formed, for instance, by chemical deposition including inkjet printing. The thin electrocatalyst layer 4c may act to facilitate transfer of electrons from the electrode to the electrolyte and thus increase cell efficiency.

### Exemplary Preparation of Electrodes 1, 4

Transparent conductive glass may be used for the substrates in the construction of negative electrode 1 and positive electrode 4 of PECSC 100 of FIG. 1. Transparent conductive glass may include a glass plate 1a, 4a and a thin conductive layer 1b, 4b. Such plates may be cut into the desired dimensions from a commercially available larger sample. The plates may be cleaned, for example, in an ultrasonic bath, usually of alcohol. In some embodiments, cleaning may last about 30 minutes. The glass plates then may be dried by blowing them with dry clean air or dry clean inert gas. Two such cleaned and dried glass plates may be used as substrates for negative electrode 1 and positive electrode 4.

### Exemplary Preparation of Positive Electrode 4

A clean transparent conductive glass plate may be used as positive electrode 4. In some embodiments, glass plate 4a may be covered by a thin conductive layer 4b and a thin platinum layer 4c, as mentioned above, which may be deposited by chemical deposition. In some embodiments, the platinum layer 4c may be formed by inkjet printing using, as ink, hexachloroplatinic acid diluted in terpineol or isopropanol or other organic solvents. In some embodiments, Pt layer 4c may be very thin, such that solar cell 100 is at least semi-transparent and may be used in PV-conversion windows. In other embodiments, Pt layer 4c may be deposited as a thick opaque reflective layer, so as to increase the probability of photon absorption by the photosensitizer. In the latter case, the cell is opaque and acts exclusively as a non-transparent PV cell. In other embodiments, carbon nanoparticles, including carbon nanotubes, may be used as electrocatalyst in the place of Pt or in mixture with Pt, providing a comparable electrocatalyst at lower cost. In still another embodiment, a conductive polymer, for instance polypyrrole, may be used either in pure form or mixed with a small quantity of Pt and/or a small quantity of carbon nanostructures. In all cases in which a transparent PV cell is desired, the exemplary electrocatalyst forms a transparent or semi-transparent film. In the aforementioned examples, materials may be deposited by chemical techniques including inkjet printing.

### Exemplary Formation of Mesoporous TiO₂ Film 2

Formation of an exemplary thin TiO₂ film 2 on transparent conductive glass electrode 1 may be made, for instance, by purely chemical processes by employing a colloidal solution, for example, in which controlled solvolysis and polymerization of titanium isopropoxide takes place. For instance, in a premeasured volume of ethanol, a premeasured quantity of a surfactant may be added. The surfactant may comprise the commercially available Triton X-100 [polyoxyethylene-(10) isooctylphenyl ether], another surfactant of the Triton family, or any other surfactant of any other category, preferably non-ionic, at a weight percentage that varies according to the chosen composition. An excess of commercially available acetic acid (“AcOH”) may be added, followed by addition of a premeasured volume of commercially available titanium isopropoxide, under vigorous stirring. This exemplary mixture eventually converts into a solid gel (e.g., a sol-gel process) through chemical reactions that lead to solvolysis and inorganic polymerization of titanium isopropoxide, that is, formation of —O—Ti—O-networks.

Before completion of this process and while formation of TiO₂ oligomers is advanced, conductive glass plate 1 may be dipped into the above-described colloidal solution and withdrawn at a constant and controlled speed, resulting in formation of a homogeneous film made of nanocomposite organic-inorganic material. In some embodiments, the homogeneous film made of nanocomposite organic-inorganic material may be deposited by spin-coating or by simple casting. In other embodiments, the homogeneous film made of nanocomposite organic-inorganic material may be deposited by inkjet printing either in stripes or in uniform layers. Successive layers of the organic-inorganic material could also be formed by repeating the above procedure in order to achieve the desirable thickness. The resulting film may be left to dry, for instance, under ambient conditions, and then it is introduced into an oven, where it may be calcined at about 500° C.-550° C., for example for about 15 minutes. Heating at such a high temperature preferably burns off all organic content such that an exemplary remaining film consists only of pure TiO₂ nanoparticles.

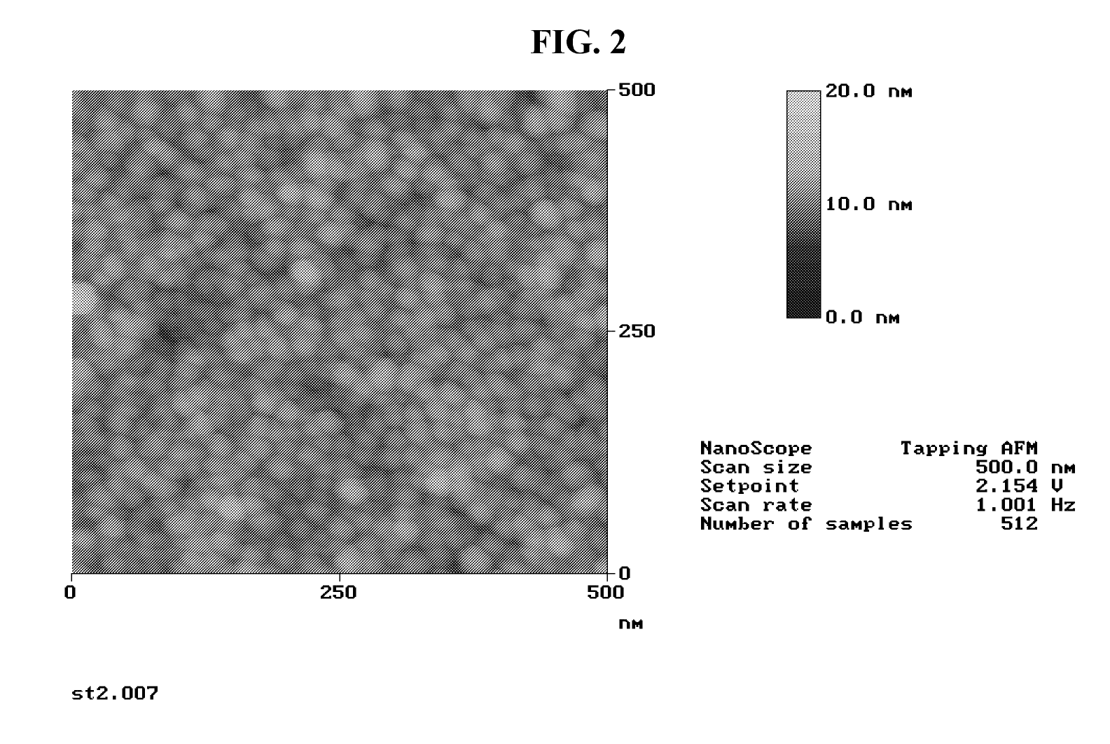

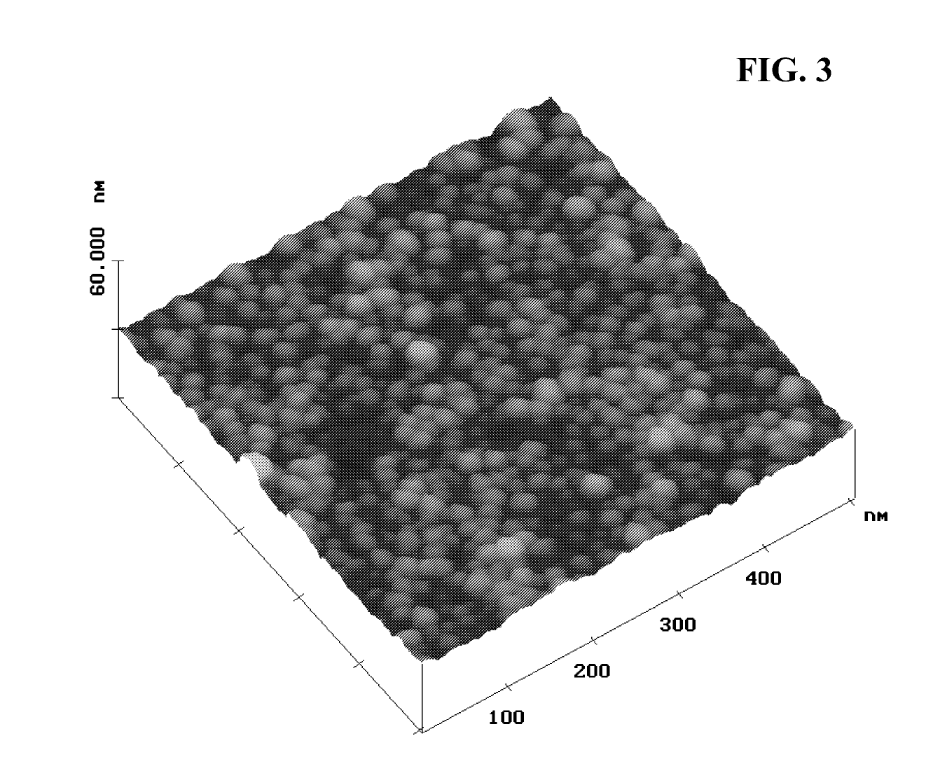

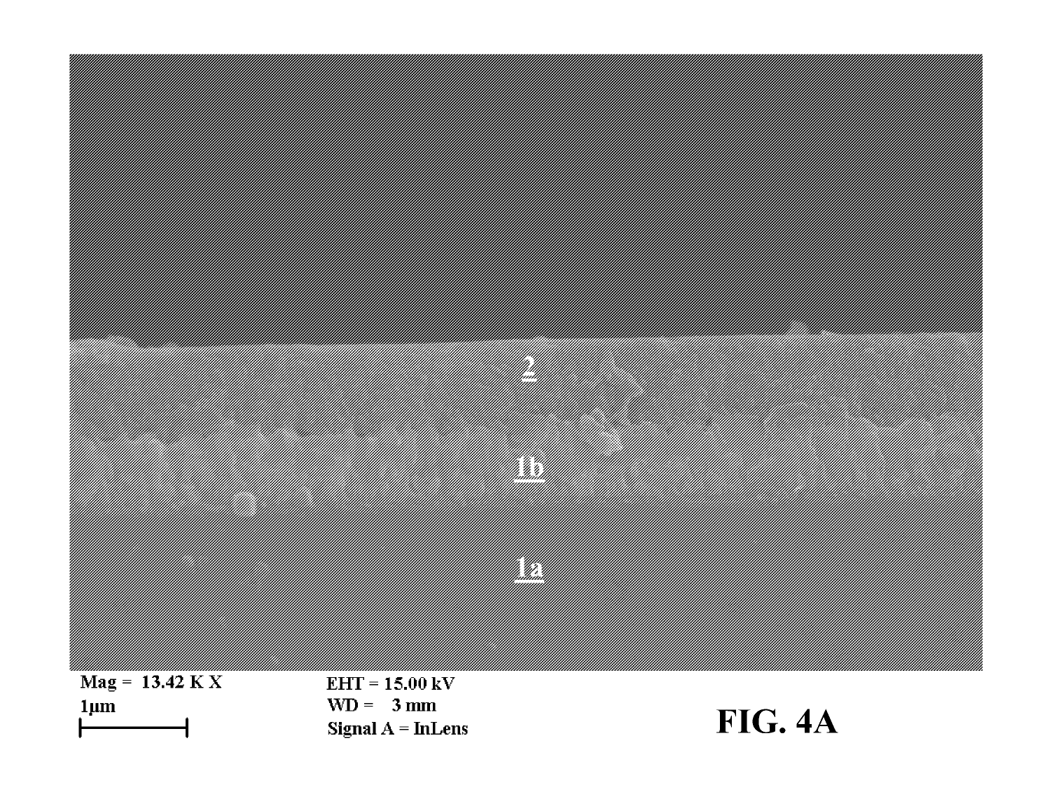

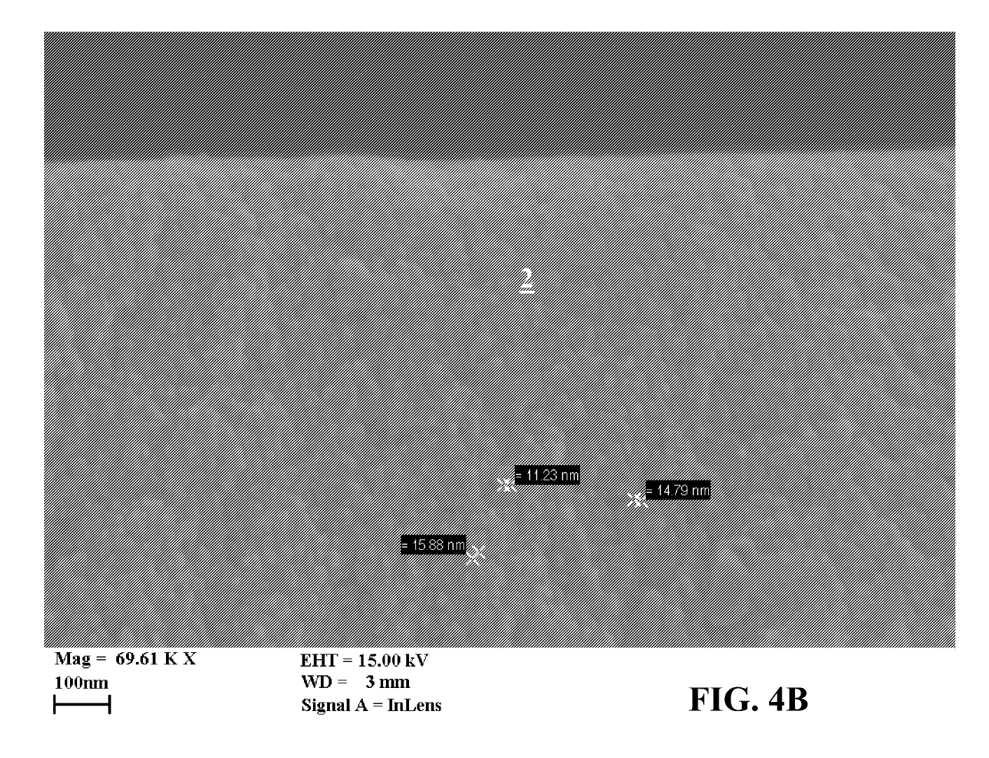

A thin film 2 may be completely transparent while a thick film 2 might become opaque, due to extensive scattering of light. An exemplary film 2 made by an above-described procedure may include TiO₂ nanoparticles having an average diameter of about 10 nm to about 30 nm in some embodiments, and less that about 10 nm in other embodiments, as characterized by microscopy methods, such as Field Emission Scanning Electron Microscopy (“FE-SEM”), Transmission Electron Microscopy (“TEM”), and Atomic Force Microscopy (“AFM”). Exemplary plan-view and perspective-view AFM images of an exemplary film 2 are shown in FIGS. 2 and 3. Moreover, FIGS. 4A and 4B depict cross-sectional images of an exemplary film 2 in lower magnification (FIG. 4A) and higher magnification (FIG. 4B). In accordance with exemplary embodiments of the invention, application of film 2 generally is made only on one side of glass plate 1, e.g., the side to be used for conduction. In these embodiments, the other side of glass plate 1 temporarily may be covered by a protective tape, especially in the event that film 2 is formed by dipping glass plate 1 into a colloidal solution.

### Exemplary Addition of a Photosensitizer to Film 2

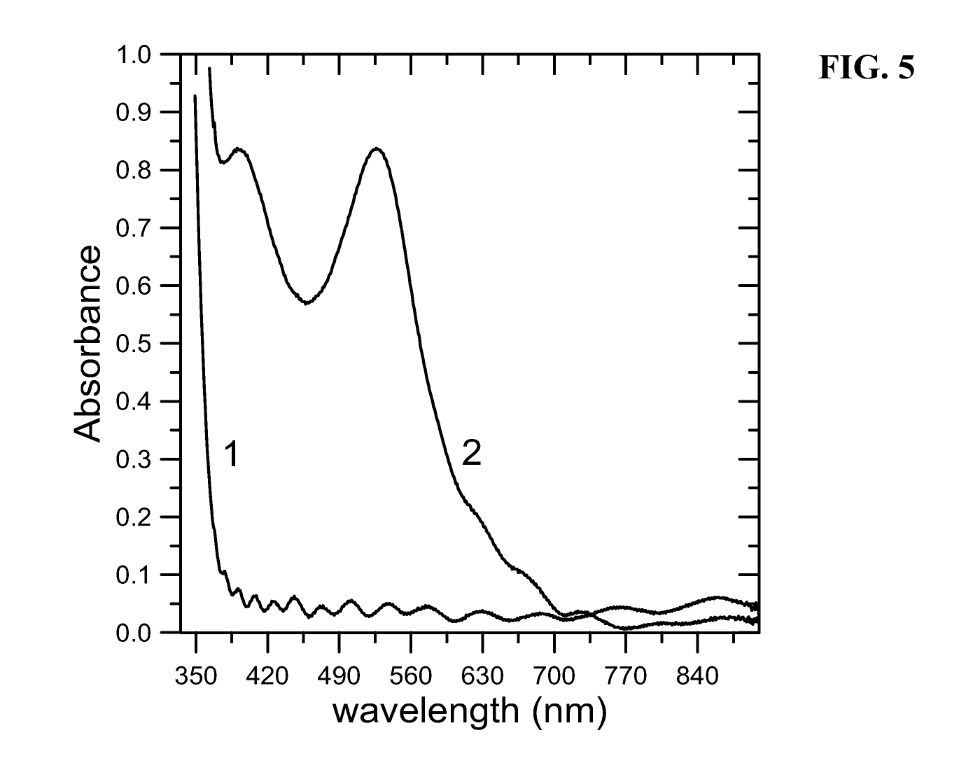

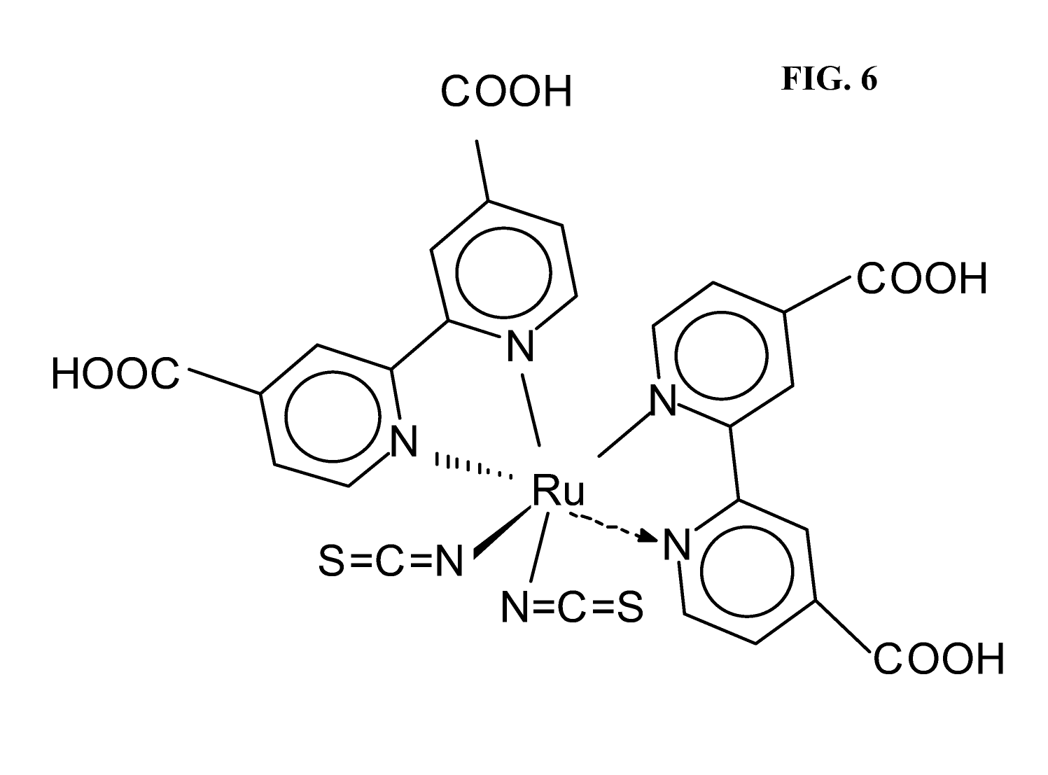

Referring to FIG. 5, Curve 1 shows an exemplary adsorption spectrum of a titania film without an adsorbed dye (e.g., native TiO₂ nanocrystallites), whereas Curve 2 shows an exemplary adsorption spectrum of a titania film with an adsorbed dye. As shown in Curve 1 of FIG. 5, native TiO₂ nanocrystallites absorb light only in the Near UV range. As such, exemplary embodiments of the invention photosensitize TiO₂ to the visible wavelength range to exploit visible light. In accordance with aspects of the invention, TiO₂ may be photosensitized using an organometallic dye capable of injecting, when excited, electrons into the conduction band of TiO₂. In exemplary embodiments, TiO₂ may be photosensitized using a commercially available ruthenium complex with the exemplary chemical structure cis-bis(isothiocyanato)bis(2,2′-bipyridyl-4,4′-dicarboxylato)-ruthenium(II). FIG. 6 depicts an exemplary chemical structure of this commercially available ruthenium complex dye. Attachment of the dye on the TiO₂ surface may be made by chemical bonding by means of the carboxylate groups, for example. The dye may be attached by adsorption on titania nanocrystallites, for example, by dipping in an ethanolic solution of the dye. Adsorption, for example, may be verified by absorption spectrophotometry, for instance.

Under the above conditions, a maximum optical density of a TiO₂/photosensitizer combination that remains transparent exceeded about 0.80, absorbance, for instance, with about 84% absorption of incident light 20 at the absorption maximum (see Curve 2 of FIG. 5). In some embodiments, this percentage may be increased or decreased by controlling the thickness of TiO₂ film 2. This 84% absorption achieved by embodiments of the invention is thought to be one of the highest percentages internationally achieved to date for transparent titania films. As such, the invention appears to be more effective and more efficient than much of the related prior art. In particular, methods in accordance with the invention appear to endow titania film 2 with an extensively porous structure and an increased active surface that may achieve increased adsorption and bonding of the photosensitizer molecules.

### Exemplary Formation of Nanocomposite Organic-Inorganic Solid Gel 3

Electrolyte solid gel 3 is disposed between electrodes 1 and 4 to enable a complete circuit. Exemplary formation of solid gel 3 may include preparation of a colloidal solution that contains a silicon alkoxide, a titanium alkoxide, or an alkoxide of another metal, that polymerizes in the presence of AcOH and ambient humidity to yield an —O-M-O— network, where M is a metal or Si. In some embodiments, gel formation is due to (inorganic) polymerization —O-M-O—. In the colloidal solution, an organic material may be incorporated in the gel and may form an organic subphase that provides ionic conductivity. Exemplary substances include surfactants and ethylene glycol oligomers or polymers, incorporated, for instance, by simple mixture or by chemical bonding with the —O-M-O— network. An organic solvent may be added, and also incorporated in the gel, that facilitates the formation of the organic subphase and the increase of ionic conductivity. Furthermore, a redox couple, such as I₃⁻/I⁻, may be added to the colloidal solution. This I₃⁻/I⁻ couple may be produced in the presence of I₂ and an iodide salt XI, wherein X⁺ is an elemental or an organic cation.

In accordance with the aforementioned parameters, the colloidal solution slowly gels after AcOH addition. AcOH may act as a gel-control factor through ester formation M-O—Ac or through slow water production by interaction between AcOH and alcohol. Use of AcOH as a gel-control factor through ester formation is mentioned in E. Stathatos, P. Lianos, U. Lavrencic-Stangar, and B. Orel, Adv. Mater., 2002, 14, No. 5, 354-357; and in E. Stathatos and P. Lianos, B. Orel, A. Surca Vuk, and R. Jese, Langmuir, 2003, vol. 19, issue 18, 7587-7591.

### Exemplary Formation of the PECSC

Once gel formation of the above-described exemplary solution (precursor to solid gel 3) is partially, but sufficiently advanced, and while the solution is still a fluid, a small volume of the solution (e.g., one drop) may be cast onto negative electrode 1. Electrodes 1 and 4 then may be brought into contact by pressing them together. Solid gel 3 consequently may spread over the whole active surface of electrodes 1 and 4 as electrodes 1 and 4 are compressed. As gel formation progresses, electrodes 1 and 4 may be durably adhered, e.g., held together strongly, such that even under stress, they are not easily detached, and hence the adhesion is stable. After PECSC 100 formation is near completion, e.g., upon compression and gelatinization of solid gel 3, solid gel 3 may comprise an electrolyte layer having a thickness of between about 50 and about 80 micrometers. Adhesion of electrodes 1 and 4 may be obtained, for instance, by —O-M-O— bonds. Ohmic contacts 5, 6 (e.g., (+) and (−), respectively) may be formed on electrodes 1 and 4 by application of electroconductive paste, inkjet printable colloidal nanoparticles of silver or of other metals or metal alloys (e.g. Nickel, Copper), epoxy paste enriched with silver grains, or copper adhesive tape, for instance, or by any other known means, which preferably is commercially available.

### Exemplary PECSC Embodiments

Various exemplary PECSC 100 embodiments are possible in accordance with the invention. Numerous applications of these embodiments are contemplated as well. For example, exemplary PECSC 100 embodiments in accordance with the invention may be used as independent energy sources connected to isolated devices or to the electricity grid. Low energy consumption apparatus, such as watches or small calculators, may be powered by a combination of small size cells. An exemplary PECSC 100 also may be used as light sensor, wherein the presence of light is signaled by an electric signal. In addition, the semi-transparency of some embodiments may allow such embodiments to be used as photovoltaic windows in buildings.

Described below are several specific examples of embodiments in accordance with the invention. The examples are not intended to limit the scope of the invention, which is defined by the claims issuing herefrom.

### Example 1

A first exemplary PECSC 100 was formed comprising the following layer stack 10. A glass plate 1a bearing a SnO₂:F layer 1b was used as negative electrode 1 and as a substrate for deposition of titania film 2. Positive electrode 4 included a glass plate 4a bearing a SnO₂:F layer 4b as a substrate for deposition of a thin layer 4c of platinum. Positive electrode 4 included a semi-transparent Pt layer 4c of a thickness of about 200 nm formed by spin-casting of an isopropanol solution of hexachloroplatinic acid.

On negative electrode 1, a colloidal solution was deposited from which titania film 2 was produced after calcination. The colloidal solution was made as follows: about 3 g ethanol (“EtOH”) were mixed with about 0.71 g Triton X-100. Then, about 0.64 g AcOH and about 0.36 g titanium isopropoxide were added under vigorous stirring and ambient conditions. After about 30 minutes of stirring, approximately one drop of this colloidal solution was placed on negative electrode 1, and the drop was stretched over the glass plate by using a glass blade. After drying for about five minutes, negative electrode 1 was placed in a preheated oven and calcined at about 550° C. for about ten minutes, at which point it was taken out from the oven and allowed to cool at ambient conditions. This procedure was repeated ten times to obtain a thin transparent film 2 of about 2 μm thick. Titania film 2 thus obtained was mesoporous and had the structure seen in the attached AFM image of FIG. 2.

Film 2 then was dipped into an ethanol solution of cis-bis(isothiocyanato)bis(2,2′-bipyridyl-4,4′-dicarboxylato)-ruthenium(II) at a concentration about 5×10⁻⁵ M. The dye was adsorbed and attached on titania mesoporous film 2, which became colored. The related absorption spectra are presented in FIG. 5. Maximum absorbance in the visible spectrum exceeds 0.80, up to about 84%.

On electrode 1 was placed about one drop of the fluid gel that bears the redox couple and becomes solid gel 3. This solid-gel-3-forming solution was prepared under ambient conditions as follows: about 1.5 ml propylene carbonate were mixed with about 1 ml Triton X-100, followed by addition of about 0.35 g tetramethoxysilane (“TMOS” or “Si(OCH₃)₄”) and about 0.65 ml AcOH under vigorous stirring. Lastly, about 0.05M iodine (“I₂”) and about 0.5M potassium iodide (“KI”) were added, and the mixture was continuously stirred for about 12 hours. The solid-gel-3-forming mixture was then ready to be applied, and approximately a single drop was cast onto film 2.

PECSC 100 was completed by attachment of positive electrode 4, which was done simply by pressing by hand electrodes 1 and 4 against each other, sandwiching the drop of solid-gel-3-forming mixture between them. Ohmic contacts 5, 6 (e.g., (+) and (−), respectively) were made using silver paste. For this reason, a small part of negative electrode 1 was protected against TiO₂ deposition to allow contact with the underlying SnO₂:F layer. When cell 100 of Example 1 was illuminated by simulated solar radiation of an intensity of about 100 mW/cm², it produced a short circuit current of about 11.8 mA/cm² and an open circuit voltage of about 0.60 volts, with a fill factor of about 0.69, and an overall efficiency of about 4.9%.

### Example 2

A PECSC was formed with the same components as that of Example 1, using the same proportions of the employed reagents and the same methods of preparation, with the exception that, in preparation of solid gel 3, propylene carbonate was replaced with an approximately 1:1 mixture of propylene carbonate and ethylene carbonate. Under illumination by simulated solar radiation of about 100 mW/cm², PECSC of Example 2 produced about 11.6 mA/cm² short circuit current, about 0.62 volts of open circuit voltage, a fill factor of about 0.69, and an overall efficiency of about 5.0%.

### Example 3

A PECSC was formed with the same components as that of Example 1, using the same proportions of the employed reagents and the same methods of preparation, with the exception that, in preparation of solid gel 3, propylene carbonate was replaced with poly(ethylene glycol)-200. When illuminated by simulated solar radiation of about 100 mW/cm², PECSC of Example 3 produced about 12.4 mA/cm² short circuit current, about 0.61 volts of open circuit voltage, a fill factor of about 0.7, and an overall efficiency of about 5.3%.

### Example 4

A PECSC was formed with the same components as that of Example 1, using the same proportions of the employed reagents and the same methods of preparation, with the exception that, in preparation of solid gel 3, propylene carbonate was replaced with propylene carbonate containing a few drops of pyridine. When illuminated by simulated solar radiation of about 100 mW/cm², PECSC of Example 4 produced about 8.4 mA/cm² short circuit current, about 0.69 volts of open circuit voltage, a fill factor of about 0.68, and an overall efficiency of about 3.9%.

### Example 5

A PECSC was formed with the same components as that of Example 1, using the same proportions of the employed reagents and the same methods of preparation, with the exception that, in preparation of solid gel 3, KI was replaced with 1-methyl-3-propylimidazolium iodide. When illuminated by simulated solar radiation of about 100 mW/cm², PECSC of Example 5 produced about 12.9 mA/cm² short circuit current, about 0.65 volts of open circuit voltage, a fill factor of about 0.66, and an overall efficiency of about 5.4%.

### Example 6

A PECSC was formed with the same components as that of Example 1, using the same proportions of the employed reagents and the same methods of preparation, with the exception that, in preparation of solid gel 3, the solid-gel-3-forming sol that contains the redox couple was made according to the following procedure: about 0.75 g Ureasil 230, e.g., a bis-triethoxysilane precursor that may be characterized by a chemical formula of:

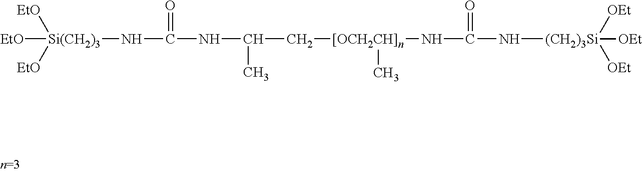

was mixed with about 1.75 g sulfolane, characterized by chemical formula:

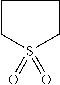

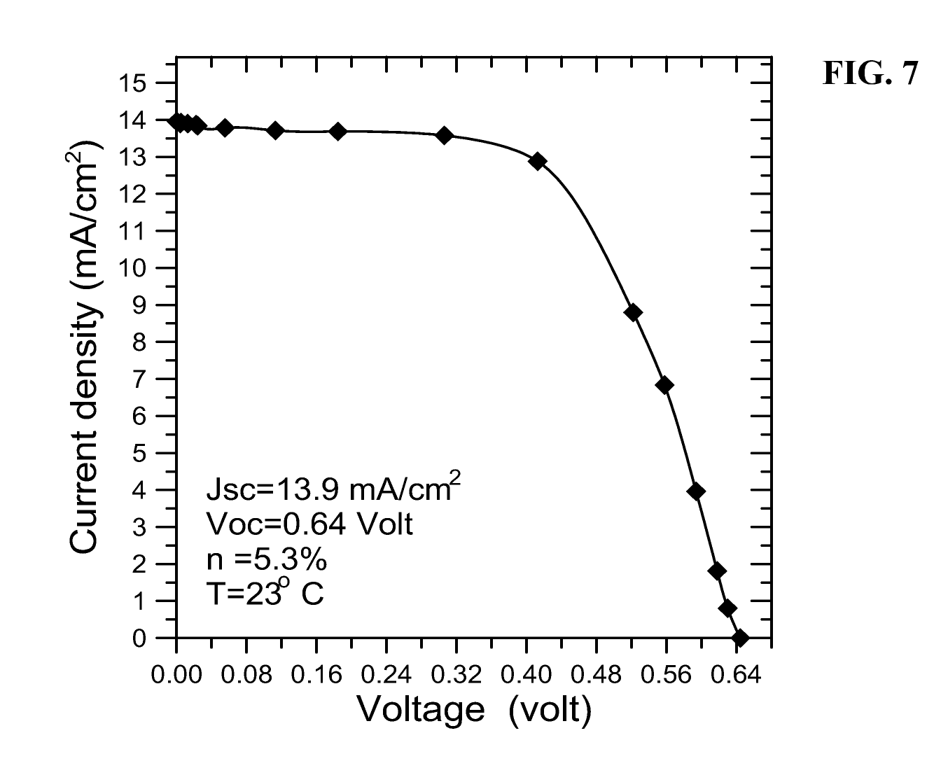

Thereafter, about 0.7 g AcOH and about 0.05M I₂+0.5M KI were added under vigorous stirring. After about 24 hours of stirring, the solid-gel-3-forming colloidal solution was ready for application, and the remainder of the cell was then completed as in Example 1. When illuminated by simulated solar radiation of about 100 mW/cm², PECSC of Example 6 produced about 13.9 mA/cm² short circuit current, about 0.64 volts of open circuit voltage, a fill factor of about 0.70, and an overall efficiency of about 5.3%. The corresponding J-V curve is shown in FIG. 7.

### Example 7

A PECSC was formed with the same components as that of Example 1, using the same proportions of the employed reagents and the same methods of preparation, with the exception that, in preparation of solid gel 3, the solid-gel-3-forming sol that contains the redox couple was made according to the following procedure: about 0.54 g Ureasil 2000, e.g., a bis-triethoxysilane precursor that may be characterized by a chemical formula of:

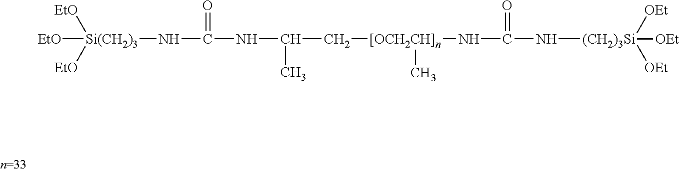

was mixed with about 1.75 g sulfolane, 0.7 g AcOH and about 0.05M I₂+0.5M KI which were added under vigorous stirring. When illuminated by simulated solar radiation of about 100 mW/cm², PECSC of Example 7 produced about 11.4 mA/cm² short circuit current, about 0.65 volts of open circuit voltage, a fill factor of about 0.65, and an overall efficiency of about 4.8%.

### Examples 8-14

Each PECSC preparation of Examples 1-7 was replicated, with the exception that, in preparation of solid gel 3, the redox couple (0.05M I₂+0.5M KI) was substituted by redox couple (0.06M I₂+0.3M KI+0.3M 1-methyl-3-propylimidazole iodide). The overall efficiency increased by about 10% compared with the PECSC Examples 1-7 made of the initial redox couple (0.05M I₂+0.5M KI).

### Examples 15-21

Each PECSC preparation of Examples 8-14 was replicated, with the exception that, in preparation of solid gel 3, 0.6M 1-methylbenzimidazole, 0.6M 2-amino-1-methylbenzimidazole, 0.2M guanidine thiocyanate, or 0.5M 4-tertiary butyl pyridine was added to the solid-gel-3-forming sol containing the redox couple (0.06M I₂+0.3M KI+0.3M 1-methyl-3-propylimidazole iodide). The presence of these reagents enhanced the open-circuit voltages of the corresponding cells.

### Examples 22-28

Each PECSC preparation of Examples 15-21 was replicated, with the exception that the TiO₂ colloidal solution on the negative electrode 1 was printed by an inkjet printer. As an example of a printable colloidal solution, a mixture of 4 ml EtOH with about 0.7 g Triton X-100 was used. Then 0.36 ml AcOH and about 0.32 g titanium isopropoxide were added in the previous mixture under vigorous stirring at ambient conditions. Alternatively, various other surfactant molecules or polymers may be used, such as, for instance, Tween 20, Tween 40, Pluronic F127, Pluronic P123, PEG200, and/or PEG400. The presence of the various surfactant molecules and polymers may affect the thickness and the porosity of the TiO₂ films and also may affect the particle size when their sols are inkjet-printed. Therefore, the presence of the different molecules as templates and/or precursors for TiO₂ particles affects to the overall efficiency of solar cells. Either way, better results were obtained in Examples 22-28, where inkjet-printing method was used, than in Examples 15-21. In other words, the ink jet printing method in combination with the Triton X-100 solution in Examples 22-28 formed more effective titania films than the titania films formed by repeated stretching and calcining of the solution used in Examples 15-21.

### Examples 29-35

Each PECSC preparation of Examples 22-28 was replicated, with the exception that the SnO₂:F glass plates were substituted with ITO glass plates. PECSC Examples 29-35 made of ITO glass plates had an overall efficiency of about 20% less than PECSC Examples 22-28 made of SnO₂:F glass plates.

### Example 36-42

PECSC preparation of Example 1 was replicated, with the exception that the procedure of deposition of TiO₂ films was changed by modifying the Triton X-100 content in the original sol. Triton X-100 content was varied from 0 to about 1.2 grams. The mesoporous structure of nanocrystalline titania was affected as a result, which in turn affected adsorption capacity of the dye photosensitizer. The structural properties that varied included the particle size, surface area and porosity of the TiO₂ films. Triton X-100 content was higher (0.72-1.2 grams) than in the original sol in some cases and lower (0-0.70 grams) than in the original sol in other cases. As a result, the structural characteristics of the TiO₂ films were changed. Better results were obtained in cases having about 0.70-0.72 grams of Triton X-100, and the corresponding Triton X-100 concentrations resulted in preferred structural properties, including preferred particle size, surface area and porosity of the TiO₂ films. As such, in most cases, better results were obtained with the Triton X-100 content employed in PECSC Examples 1-7 than in PECSC Examples 36-42.

The foregoing description discloses exemplary embodiments of the invention. While the invention herein disclosed has been described by means of specific embodiments and applications thereof, numerous modifications and variations could be made thereto by those skilled in the art without departing from the scope of the invention set forth in the claims. Modifications of the above disclosed apparatus and methods that fall within the scope of the invention will be readily apparent to those of ordinary skill in the art. Accordingly, other embodiments may fall within the spirit and scope of the invention, as defined by the following claims.

In the description above, numerous specific details are set forth in order to provide a more thorough understanding of embodiments of the invention. It will be apparent, however, to an artisan of ordinary skill that the invention may be practiced without incorporating all aspects of the specific details described herein.

In other instances, specific details well known to those of ordinary skill in the art have not been described in detail so as not to obscure the invention. Readers should note that although examples of the invention are set forth herein, the claims, and the full scope of any equivalents, are what define the metes and bounds of the invention.

What is claimed is:

1. A method of forming a photoelectrochemical solar cell, the method comprising:
forming a titanium dioxide layer by inkjet printing on a first electrode;
adding a dye to the titanium dioxide layer;
forming a solid gel above the titanium dioxide layer, the solid gel comprising an electrolyte layer; and
disposing a second electrode above the solid gel.

2. The method of claim 1, wherein the first electrode is transparent, the second electrode is transparent, or the first and the second electrodes are transparent.

3. The method of claim 1, wherein the first electrode and/or the second electrode comprises a thin conductive film on a substrate.

4. The method of claim 3, wherein the thin conductive film comprises SnO₂:F or ITO, and the substrate comprises glass.

5. The method of claim 3, wherein the second electrode further comprises a thin electrocatalyst layer on the thin conductive film.

6. The method of claim 5, wherein the thin electrocatalyst layer comprises platinum, carbon, or both, comprising nanoparticles, nanotubes, conjugated conductive polymers, or a mixture thereof.

7. The method of claim 1, wherein the dye comprises a photosensitizer, and wherein the photosensitizer comprises a ruthenium organometallic complex dye, a merocyanine dye, or a hemicyanine dye.

8. The method of claim 7, wherein forming the titanium dioxide layer comprises:
mixing a solution of titanium isopropoxide, an organic acid and a surfactant to trigger solvolysis and polymerization of the titanium isopropoxide;
forming a deposition of the solution on the first electrode;
calcining the deposition; and
adsorbing the photosensitizer after calcining the deposition.

9. The method of claim 1, wherein the solid gel comprises a redox couple comprising iodine (I₂), potassium iodide (KI), and 1-methyl-3-propylimidazole iodide.

10. The method of claim 1, wherein the solid gel comprises 1-methylbenzimidazole, 2-amino-1-methylbenzimidazole, guanidine thiocyanate, or 4-tertiary butyl pyridine.

11. The method of claim 1, wherein the solid gel comprises a nanocomposite organic-inorganic material and a redox couple.

12. The method of claim 1, wherein the solid gel comprises a stable adhesion layer durably adhering the first electrode and the second electrode, and wherein forming the solid gel comprises compressing the electrolyte layer between the first electrode and the second electrode, and then gelatinizing the electrolyte layer.

13. The method of claim 1, wherein the solar cell comprises a self-sealing layer stack, and wherein forming the solid gel comprises self-sealing the self-sealing layer stack.

14. The method of claim 1, wherein the solid gel has a thickness of between about 50 and about 80 micrometers.

15. A solar cell comprising:
a first electrode;
a titanium dioxide layer formed by inkjet printing on the first electrode and comprising a dye;
a solid gel disposed above the titanium dioxide layer, the solid gel comprising an electrolyte layer; and
a second electrode disposed above the solid gel.

16. The solar cell of claim 15, wherein the first electrode is transparent, the second electrode is transparent, or the first and the second electrodes are transparent.

17. The solar cell of claim 15, wherein the first electrode and/or the second electrode comprises a thin conductive film on a substrate.

18. The solar cell of claim 17, wherein the thin conductive film comprises SnO₂:F or ITO, and the substrate comprises glass.

19. The solar cell of claim 17, wherein the second electrode further comprises a thin electrocatalyst layer on the thin conductive film.

20. The solar cell of claim 19, wherein the thin electrocatalyst layer comprises platinum, carbon, or both, comprising nanoparticles, nanotubes, conjugated conductive polymers, or a mixture thereof.

21. The solar cell of claim 15, wherein the dye comprises a photosensitizer, and wherein the photosensitizer comprises a ruthenium organometallic complex dye, a merocyanine dye, or a hemicyanine dye.

22. The solar cell of claim 21, wherein the titanium dioxide layer further comprises at least one calcined film of polymerized titanium isopropoxide, and wherein the photosensitizer has been adsorbed onto the at least one calcined film.

23. The solar cell of claim 15, wherein the solid gel comprises a redox couple comprising iodine (I₂), potassium iodide (KI), and 1-methyl-3-propylimidazole iodide.

24. The solar cell of claim 15, wherein the solid gel comprises 1-methylbenzimidazole, 2-amino-1-methylbenzimidazole, guanidine thiocyanate, or 4-tertiary butyl pyridine.

25. The solar cell of claim 15, wherein the solid gel comprises a nanocomposite organic-inorganic material and a redox couple.

26. The solar cell of claim 15, wherein the solid gel comprises a stable adhesion layer durably adhering the first electrode and the second electrode.

27. The solar cell of claim 15, wherein the solar cell comprises a self-sealing layer stack.

28. The solar cell of claim 15, wherein the solid gel has a thickness of between about 50 and about 80 micrometers.

29. A transparent window comprising a transparent solar cell, wherein the transparent solar cell comprises:
a first electrode comprising a first transparent conductive glass plate;
a transparent titanium dioxide layer formed by inkjet printing on the first electrode and comprising a dye;
a transparent solid gel disposed above the transparent titanium dioxide layer, the transparent solid gel comprising an electrolyte layer; and
a second electrode disposed above the solid gel, the second electrode comprising a second transparent conductive glass plate.

30. The transparent window of claim 29, wherein the solid gel comprises a redox couple comprising iodine (I₂), potassium iodide (KI), and 1-methyl-3-propylimidazole iodide.

31. The transparent window of claim 29, wherein the solid gel comprises 1-methylbenzimidazole, 2-amino-1-methylbenzimidazole, guanidine thiocyanate, or 4-tertiary butyl pyridine.

32. The transparent window of claim 29, wherein the second electrode further comprises a thin electrocatalyst layer on the thin conductive film, and wherein the thin electrocatalyst layer comprises platinum, carbon, or both, comprising nanoparticles, nanotubes, conjugated conductive polymers, or a mixture thereof.

33. The transparent window of claim 29, wherein the dye comprises a photosensitizer, and wherein the photosensitizer comprises a ruthenium organometallic complex dye, a merocyanine dye, or a hemicyanine dye.

34. The transparent window of claim 29, wherein the solid gel comprises a stable adhesion layer durably adhering the first electrode and the second electrode.

35. The transparent window of claim 29, wherein the solar cell comprises a self-sealing layer stack.

36. The transparent window of claim 29, wherein the solid gel has a thickness of between about 50 and about 80 micrometers.
